(19) United States
(12) Patent Application Publication
(10) Pub. No.: US 2015/0003633 A1
(43) Pub. Date: Jan. 1, 2015

(54) MAX SOUND AUDIO PROGRAM

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/222,516

(22) Filed: Mar. 21, 2014

Related U.S. Application Data
(60) Provisional application No. 61/804,136, filed on Mar. 21, 2013.

(51) Int. Cl. G10L 19/26; H03G 3/20

(52) U.S. Cl. CPC G10L 19/26; H03G 3/20
USPC 381/99

(57) ABSTRACT

A process and system for enhancing and customizing sound comprises receiving an input audio sound and processing the input by one or more filter blocks to dynamically reshape the dynamic, phase and frequency content of the input audio sound. The parallel processed audio is combined in a sound mixer and tube harmonics are added to the output from the mixer. The tube harmonics added audio is fed to a highpass filter which sets a frequency limit of audio passing through this block. A low pass filter movines the audio in a plus or minus direction with a dynamic envelope control. A frequency divider is provided for shifting audio sound below a selected frequency down an octave. Output from this stage is edited by feeding a certain amount of each side of the audio to a corresponding opposite side. The frequency balance is adjusted by setting a band phase coherent equalizer for frequency adjustments. The original, unprocessed sound is then mixed with the processed audio. Gain is adjusted and the processed sound is outputted for use.

### CROSS-REFERENCE TO RELATED PATENT APPLICATIONS

Embodiments of the present invention relate to U.S. Provisional Application Ser. No. 61/804,136, filed Mar. 21, 2013, entitled “AUDIO PROGRAM”, the contents of which are incorporated by reference herein and which is a basis for a claim of priority.

### BACKGROUND OF THE INVENTION

With almost all audio sounds received through a medium being somewhat compressed, there is an increasing need for enhancement for audio of all types such as MP3, streaming internet music, broadcast audio, audiobooks, cable programming audio, just about any kind of transmitted or broadcast audio. A main cause of the compression is reduced available bandwidth for both broadcast and internet (terrestrial and extra terrestrial) media. The future of this bandwidth is simple, there is not enough bandwidth to support the growing need and will only get worse.

The finite amount of bandwidth available, and the unavailability of much hope for expansion to meet the demand, has resulted in continuing narrowing of available bandwidths. As a result of increased demand, the quality of audio will also be lessened, this, in turn, leads to a loss in both harmonic and dynamic content. The only available solution is to add even more compression, or change the audio format to a compressed format (mp3, AAC, etc.) for a small footprint. More compression equals a much less audio quality for the end user. As far as anything with video goes, there is no way to compress video without a high degree of noticeable degradation, but degrading the audio is an acceptable practice.

In computer science and information theory, data compression, source coding, or bit-rate reduction involves encoding information using fewer bits than the original representation. Compression can be either lossy or lossless. Lossless compression reduces bits by identifying and eliminating statistical redundancy. No information is lost in lossless compression. Lossy compression reduces bits by identifying unnecessary information and removing it. The process of reducing the size of a data file is popularly referred to as data compression, although its formal name is source coding (coding done at the source of the data before it is stored or transmitted)¹. ¹ http://en.wikipedia.org/wiki/Audio_compression_(data)#Audio

Compression is useful because it helps reduce resource usage, such as data storage space or transmission capacity. Because compressed data must be decompressed to use, this extra processing imposes computational or other costs through decompression; this situation is far from being a free lunch. Data compression is subject to a space-time complexity trade-off. For instance, a compression scheme for video may require expensive hardware for the video to be decompressed fast enough to be viewed as it is being decompressed, and the option to decompress the video in full before watching it may be inconvenient or require additional storage. The design of data compression schemes involves trade-offs among various factors, including the degree of compression, the amount of distortion introduced (e.g., when using lossy data compression), and the computational resources required to compress and uncompress the data². ² See, n.1, above

There is a need for a process and system that can restore sound quality without the problems of the conventional systems and techniques.

### SUMMARY OF THE INVENTION

With the inventive Max Sound Program (third version), a compressed audio can be processed and restored to much of its original quality by virtue of how the system works. The program is extremely dynamic in the way that it works and resynthesizes the missing content at a higher level than any other conventional process.

A process and system for enhancing and customizing sound comprises receiving an input audio sound and processing the input by one or more filter blocks to dynamically reshape the dynamic, phase and frequency content of the input audio sound. The filter block processed audio is combined in a sound mixer and tube harmonics are added to the output from the mixer. The tube harmonics added audio is fed to a highpass filter which sets a frequency limit of audio passing through this block. A low pass filter moves the audio in a plus or minus direction with a dynamic envelope control. A frequency divider is provided for shifting audio sound below a selected frequency down an octave. Output from this stage is edited by feeding a certain amount of each side of the audio to a corresponding opposite side. The frequency balance is adjusted by setting a band phase coherent equalizer for frequency adjustments. The original, unprocessed sound is then mixed with the processed audio. Gain is adjusted and the processed sound is outputted for use.

### BRIEF DESCRIPTION OF THE DRAWINGS

FIG. 1 is a detailed program interface of an exemplary embodiment of the present invention.

FIG. 2 is a block diagram of the overall operation of an exemplary embodiment of the present invention.

FIG. 3 is a program interface of filter blocks according to an exemplary embodiment of the present invention.

FIG. 4 is a program interface of tube simulation according to an exemplary embodiment of the present invention.

FIG. 5 is a program interface of the Sparkle block according to an exemplary embodiment of the present invention.

FIG. 6 is a program interface of the Expander block according to an exemplary embodiment of the present invention.

FIG. 7 is a program interface of Bass Expander process according to an exemplary embodiment of the present invention.

FIG. 8 is a program interface of Cross-fade according to an exemplary embodiment of the present invention.

FIG. 9 is a program interface of Equalization step according to an exemplary embodiment of the present invention.

FIG. 10 is a program interface of Output Mixer step according to an exemplary embodiment of the present invention.

### DETAILED DESCRIPTION OF THE PREFERRED EMBODIMENT(S)

Details of the present invention will now be discussed by reference to the drawings.

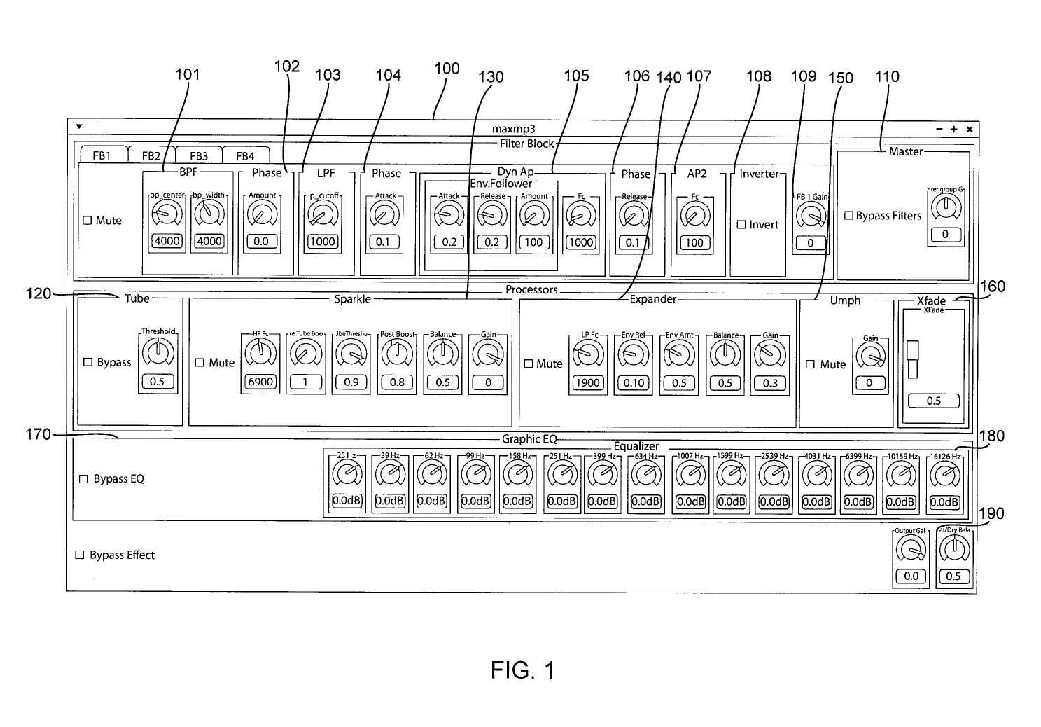

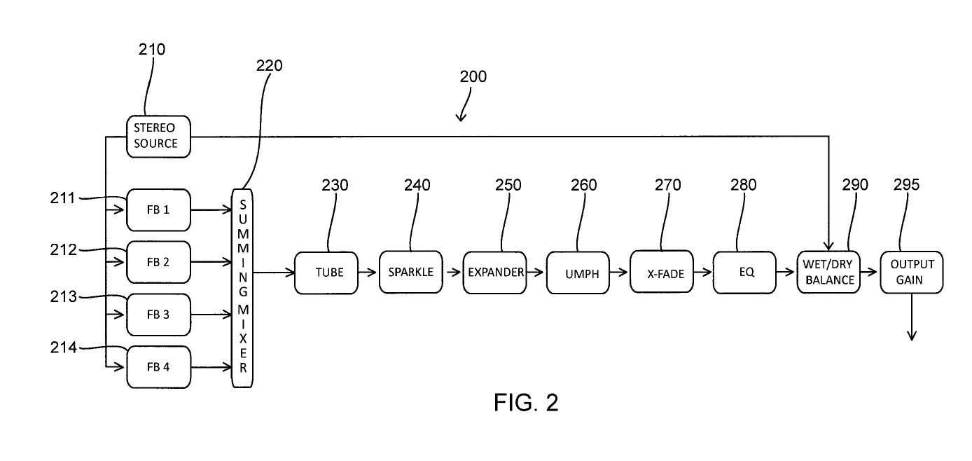

FIG. 1 is a detailed program interface of an exemplary embodiment of the present invention, which corresponds to a new and improved version of the Max Sound Program for processing audio. In one embodiment, execution of the inventive process requires a computer with a sound card. FIG. 1 shows the various processing steps depicted in the block diagram of FIG. 2, including, Filter Blocks 100, Summing Mixer 110, Tube 120, Sparkle 130, Expander 140, UMPH 150, Cross fade (X-Fade) 160, Equalizer 170, Wet/Dry Balance 180 and Output Gain adjustment 190. The corresponding value range for each one of these parameters and settings according to an exemplary embodiment of the present invention is shown in FIG. 1.

FIG. 2 is a block diagram of the process steps of the present invention according to an exemplary embodiment. Stereo Source (input audio) 210 is split into two paths as it enters the process. One side enters the process through the Filter Banks, and the other enters through the Wet/Dry 290 Balance control. In one embodiment, there are four identical banks 211 to 214 assigned to different, potentially overlapping ranges. The inputs of these four banks are all parallel so that they each receive the same full range signal from the original Stereo Source 210.

Continuing with reference to FIG. 2 and FIG. 1, in each Filter Bank 211 to 214, the signal is first received by a bandpass filter 101 to select the general operating range of this bank. There is a center frequency and a bandwidth control for adjustment of this range. Next is a Phase knob 102 which controls a maximum amount of phase shift for the range of the bandpass filter 101. This amount of phase shift is modified from a zero to a +/−amount (that amount is set by the Phase knob 102) dynamically using an envelope follower that monitors the center frequency. For example, if the amplitude for the center frequency drops below an average level (unity gain) then the amount of phase shift would take a negative direction. There is also an Attack knob 103 to allow for the selection of an amount of delay time before the phase shift reacts to a change.

Next, Dynamic All-pass filter is identified by reference numeral 105. By way of background, an all-pass filter is a signal processing filter that passes all frequencies equally in gain, but changes the phase relationship between various frequencies. It does this by varying its phase shift as a function of frequency. Generally, the filter is described by the frequency at which the phase shift crosses 90° (i.e., when the input and output signals go into quadrature—when there is a quarter wavelength of delay between them). They are generally used to compensate for other undesired phase shifts that arise in the system, or for mixing with an unshifted version of the original to implement a notch comb filter. They may also be used to convert a mixed phase filter into a minimum phase filter with an equivalent magnitude response or an unstable filter into a stable filter with an equivalent magnitude response³. ³ http://en.wikipedia.org/wiki/All-pass_filter

According to an embodiment of the present invention All-pass Filter 105 is used to dynamically change the overall phase response of the audio from the previous block. The purpose of this is to minimize any undesired phase anomalies that might have occurred in the processed audio thus far. The following are controls for envelope follower in this section. Attack—amount of time it takes for the Envelope Follower to reach its predetermined level with a preferred range of 0.0 to 1.0. Release refers to that amount of time it takes before the Envelope Follower resets itself and has a preferred range of 0.0 to 1.0. Amount determines the amount of the Envelope Follower that is applied to this signal and has a range of 0 to 5 k. FC refers to filter cutoff of the lowpass filter used in this section and has a range of 100 to 20 k.

Envelope Follower 105 constantly measures an input signal and applies that same envelope to something else as a modulator or a simple shaper. By way of background, an envelope follower is an electronic circuit which produces a control signal proportional to the envelope of an input signal. Such a device is most commonly used for allowing a synthesizer to track the dynamics of a conventional instrument, such as a guitar or a piano⁴. ⁴ http://electronicmusic.wikia.com/wiki/Envelope_follower

Phase Release control 106 is different from the one in the DYN AP section. This setting selects the amount of release time for the entire DYN AP process before it begins to change again. This means that there is an adjustment range from an abrupt, or instant, change to a slow fade in type of change. This is necessary so that there are no undesirable phase anomalies introduced into the audio.

AP2 107 is an all-pass filter to further aid in correcting undesired phase anomalies in the audio processed thus far. There is a single control for the center frequency selection.

Inverter 108 inverts the phase of a particular filter bank by. In one embodiment, the phase is inverted by 180 degrees in a negative direction.

Gain 109 controls the final output gain of a single filter bank.

Following the processing above, the audio processed by the filter banks is fed to Summing Mixer (Master) 110, which mixes the audio from all four blocks into a single stereo stream. Preferably, this step includes a Master/Group volume control that allows for the overall, mixed volume adjustment from the Summing mixer.

Tube Simulation 120 is discussed next. By way of background, a Virtual Valve Amplifier (VVA) is software for simulating the sound of various valve amplifier designs. A VVA can be used to color the sound of a digital recording by adding “tube-warmth” in addition to adding subtle harmonics to enhance very old or muffled recordings. The algorithms behind a VVA are based on real vacuum tube circuits and non-linearities, mathematically simulating the large-signal transfer functions of various vacuum tubes and output transformers found in amplifier designs. A majority of this data was originally derived from extensive bench measurements on real vacuum tube amplifier circuits under varying operating conditions by engineers Craig Maier and Rick Carlson in the early 1990s. A VVA is a direct mathematical reconstruction of the same signal passing through a physical electron tube amplifier⁵. ⁵ http://en.wikipedia.org/wiki/Virtual_Valve_Amplifier

Tube Simulation 120 simulates the characteristics of the harmonics that occur when using analog tubes in an audio path. The Threshold controls the audio level at which the tube effect starts to work. Any audio below that level is passed unchanged until the amplitude reaches the assigned amount. A Bypass is provided so that audio can be sent to the next section unaffected.

Sparkle 130 shapes the harmonic content of the tube sound from the previous section and controls the amount to be added back into the processed audio before Tube Simulation 120. The controls and their preferred ranges and/or values are as follows:

HP FC—highpass filter cutoff frequency (range=4 to 10 k)

PRE TUBE BOOST—amount of boost as it enter the tube simulator (range=1 to 5)

TUBE THRESHOLD—amount of tube saturation (range=0.1 to 1.0)

POST BOOST—amount of boost after the tube simulator (range=0.1 to 2.0)

BALANCE—balance between input and tube sound mixed together (range=0.1 to 1.0)

GAIN—output gain for this section (range=−70 to 6)

MUTE—mutes this section (range=on/off).

Expander 140 takes the input audio and filters an amount determined by the cutoff (FC) that will be added back into the input audio, at the output of this section with envelope control of its level. The controls and their preferred ranges and/or values are as follows:

LP FC—lowpass frequency cutoff (range=300 to 8 k)

ENV REL—amount of time before the envelope releases (range=0.01 to .50)

ENV AMT—amount of the envelope applied to the processed signal (range=0.0 to 1.0)

BALANCE—balance between input and expander sound mixed together (range=0.0 to 1.0)

GAIN—output gain of this section (range=0.0 to 1.0)

MUTE—mute this section (range=on/off)

UMPH (Bass Expander) 150—This section is a frequency divider which takes everything from below a selected frequency and shifts it down an octave. This section has a gain for the amplitude of the octave down audio and a bypass. The lower range for this effect is fixed at 30 Hz while the upper range is adjustable, preferably from 50 Hz to 300 Hz.

Crossfade 160 feeds a small amount of Left side to Right side and Right side to Left side. According to an embodiment, there is an adjustable amount of 0.0 to 1.0 with 1.0 being a maximum of 3 dB.

EQ 170 includes three selectable EQ's here with Bypass capability. They are standard ISO centers for frequency (1 octave/10 band, ⅔ octave/15 band, ⅓ octave/31 band). Also, phase coherent allowing for extremely low phase change between frequencies.

Output Mixer 190 allows for adjustment of the WET/Dry mix and the final output gain amount 180.

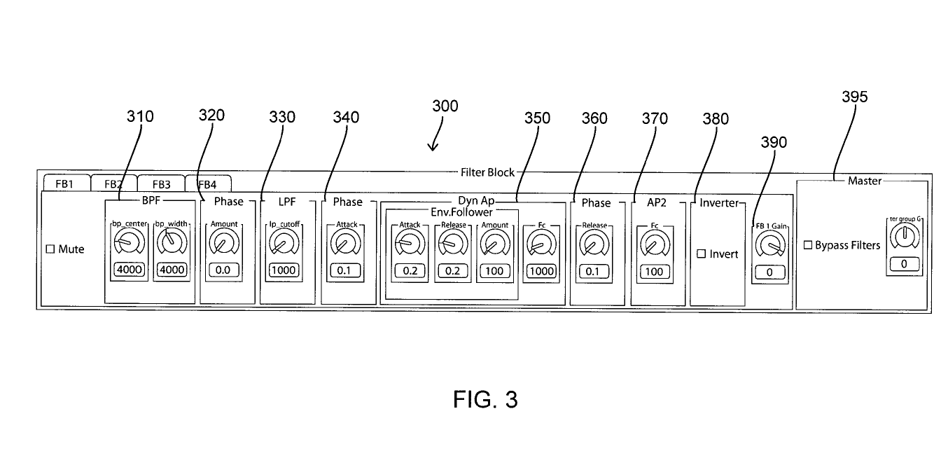

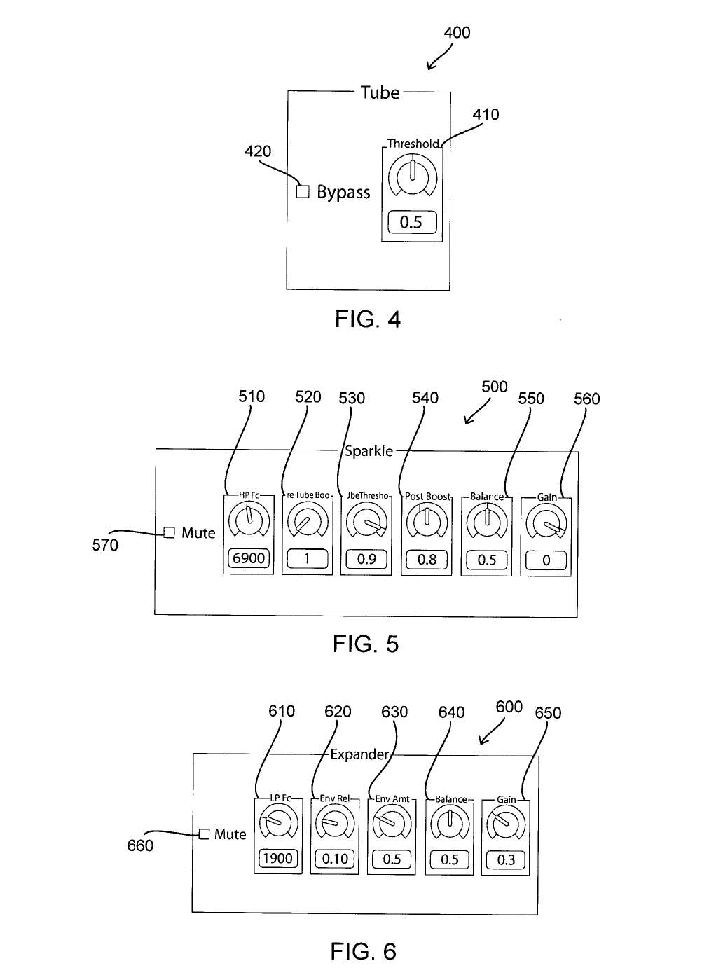

Next, an exemplary embodiment of the present invention is discussed by reference to FIG. 3 depicting Filter Block 300. BPF 310 is a bandpass filter) that includes a BP Center, which is a center frequency of this bandpass filter, with a preferred range of 100 to 20 k. BP Width sets the operating range of this bandpass filter and has a preferred range of 100 to 10 k. PHASE 320 refers to the maximum amount of phase shift allowed by this Envelope Follower specifically for this section and has a preferred range of 0 to 10. Low Pass Filter (LPF) 320 has a preferred range of 50 to 20 k. PHASE—Attack 330 is an amount of time before this Envelope is applied specifically for this section and has a preferred range of 0.1 to 0.5. In the Dynamic Allpass Filter 350 envelope Follower, Attack is an amount of time it takes for the Envelope Follower to reach its predetermined level and has a preferred range of =0.0 to 1.0. Release sets the amount of time it takes before the Envelope Follower resets itself and has a preferred range of 0.0 to 1.0). Amount determines that amount of the Envelope Follower that is applied to this signal with a preferred range of 0 to 5 k. FC—filter cutoff of the lowpass filter used in this section with a preferred range of 100 to 20 k. PHASE Release 360 sets the amount of time it takes before the Envelope Follower resets itself and has a preferred range of 100 to 15 k). ALLPASS 2 (AP 2) 370 is a second allpass filter and has a preferred range of 25 to 20 k. INVERTER 380 inverts the phase of the input signal and has a preferred range of on/off). FB GAIN 390 is the total amount of gain for this complete filter block with a preferred range of −70 to 6. MASTER 395 is the total amount of gain for all filter blocks and has a preferred range of −70 to 6.

Next, an exemplary embodiment of the present invention is discussed by reference to FIG. 4 depicting Tube Simulation 400. THRESHOLD 410 sets the level where the tube effect starts to process audio with a preferred range of 0.0 to 1.0. BYPASS 420 removes the effect from the signal path and has a preferred range=on/off.

Next, an exemplary embodiment of the present invention is discussed by reference to FIG. 4 depicting Sparkle block (Tube Simulator) 500. HP FC 510 is a highpass filter cutoff frequency with a preferred range of 4 to 10 k. PRE TUBE BOOST 520 sets the amount of boost as it enter the tube simulator and has a preferred range of 1 to 5). TUBE THRESHOLD 530 determines the amount of tube saturation and has a preferred range of 0.1 to 1.0). POST BOOST 540 is the amount of boost after the tube simulator with a preferred range of 0.1 to 2.0. BALANCE 540 sets the—balance between input and tube sound mixed together (range=0.1 to 1.0) 6. GAIN 550 is the output gain for this section and has a preferred range of −70 to 6. MUTE 570 acts to mutes this section and its preferred values are on/off.

Next, an exemplary embodiment of the present invention is discussed by reference to FIG. 6 depicting Expander block 600. LP FC 610 sets the lowpass frequency cutoff and has a preferred range of 300 to 8 k. ENV REL 620 determines the amount of time before the envelope releases, and has a preferred range of 0.01 to 0.50. ENV AMT 630 sets the amount of the envelope applied to the processed signal with a preferred range of 0.0 to 1.0. BALANCE 640 determines the balance between input and expander sound mixed together and has a preferred range of 0.0 to 1.0. GAIN 650 is the output gain of this section and has a preferred range of 0.0 to 1.0. MUTE 660 mutes the operation of this section with a preferred range=on/off.

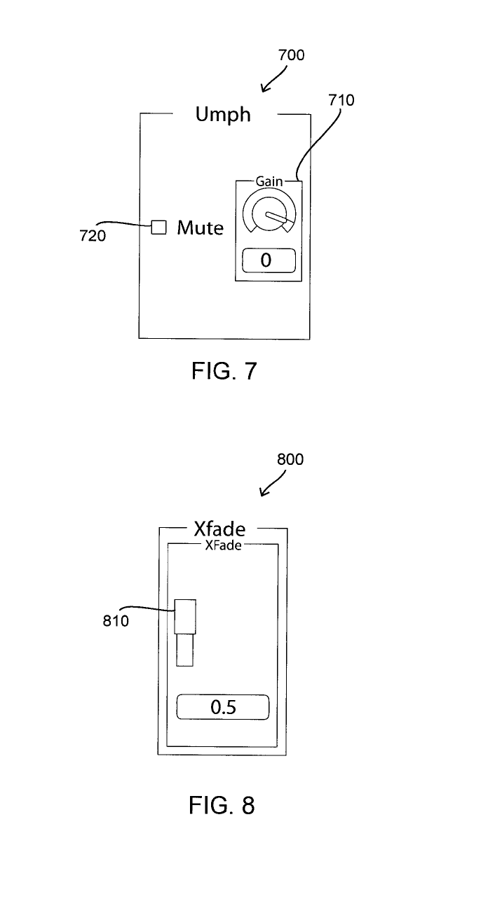

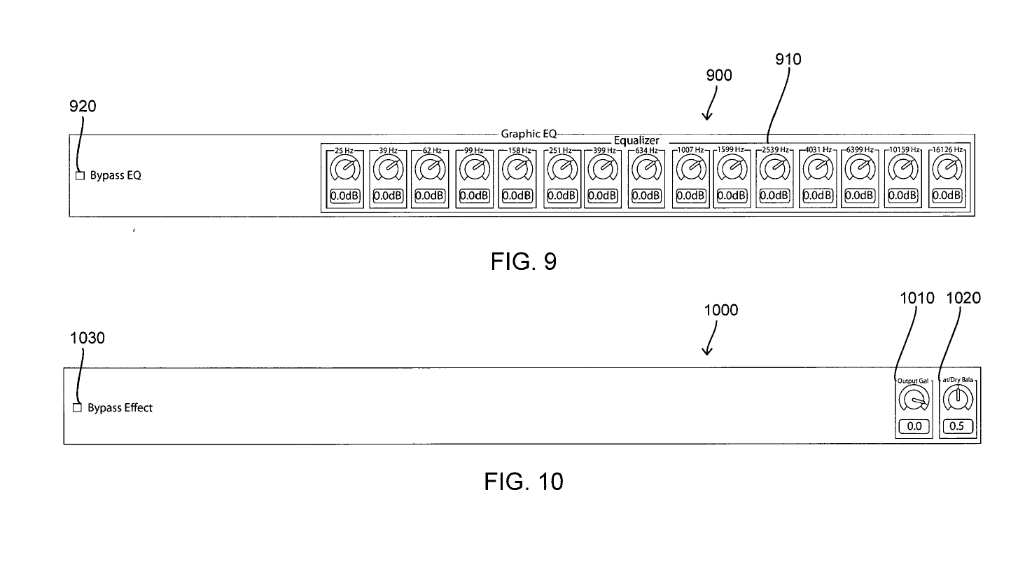

Next, an exemplary embodiment of the present invention is discussed by reference to FIG. 7 depicting UMPH (Bass Expander) block 700. GAIN 710 is output gain of this section with a preferred range of −70 to 6). MUTE 720 mutes the operation of this section with a preferred range=on/off.

Next, an exemplary embodiment of the present invention is discussed by reference to FIG. 6 depicting Crossfade block 800. X FADE AMOUNT 810 is the amount of each side fed into the opposing side and has a preferred range of 0.0 to 1.0.

Next, an exemplary embodiment of the present invention is discussed by reference to FIG. 6 depicting Equalization Section 900 block. EQ 910 allows for phase coherent equalization of input audio, for e.g., 10, 15, or 31 band and has a preferred range of −50 to 25. BYPASS EQ bypasses the EQ section and has a preferred range of on/off.

Next, an exemplary embodiment of the present invention is discussed by reference to FIG. 6 depicting Output Mixer 1000. WET/DRY BALANCE 1010 sets the balance between the original stereo source (210 in FIG. 2) and the processed stereo audio and has a preferred range of −70 to 8.0. OUTPUT GAIN 1020 sets the final output gain of the sound processed by the inventive process and has a preferred range of range—0.0 to 10.00. Bypass 1030 acts to bypass this section.

What is claimed is:

1. A process and system for enhancing and customizing sound comprising:
Receiving an input audio sound;
Processing the input by one or more filter blocks to dynamically reshape the dynamic, phase and frequency content of the input audio sound;
Combining the processed input audio sounds in a mixer;
Adding tube harmonics to the output from the mixer;
Providing the tube harmonics added audio to a highpass filter which sets a frequency limit of audio passing through this block;
A low pass filter for moving the audio in a plus or minus direction with a dynamic envelope control;
A frequency divider for shifting audio sound below a selected frequency down an octave;
Editing sound output by feeding a certain amount of each side of the audio to a corresponding opposite side;
Adjusting a sound frequency balance by setting a band phase coherent equalizer for frequency adjustments;
Mix the original unprocessed audio with the processed audio;
Adjust Gain;
Output the processed sound for use.

2. The process of claim 1, wherein the number of the filter blocks is four.

3. The process of claim 2, wherein the processing is performed in parallel.
